(19) United States
(12) Patent Application Publication
(10) Pub. No.: US 2010/0327332 A1
(43) Pub. Date: Dec. 30, 2010

(54) SOLID STATE IMAGING DEVICE

(76) Inventors: Toru Okino, Osaka (JP); Mitsuyoshi Mori, Kyoto (JP); Kazuo Jujiwara, Toyama (JP)

Correspondence Address: MCDERMOTT WILL & EMERY LLP, 600 13TH STREET, NW, WASHINGTON, DC, 20005-3096, US

(21) Appl. No.: 12/667,997

(22) PCT Filed: Jun. 29, 2009
(86) PCT No.: PCT/JP2009/002986

§ 371 Date: Jan. 6, 2010

(30) Foreign Application Priority Data
Aug. 29, 2008 (JP) 2008-221691

(51) Int. Cl. H01L 31/112

(52) U.S. Cl. 257/292; 257/E31.053

(57) ABSTRACT

A solid state imaging device having a pixel area in which a plurality of light receiving elements are arranged, and a peripheral circuit area adjacent to the pixel area includes: a semiconductor substrate 102 of a first conductivity type or a second conductivity type; a first semiconductor layer 103 of the first conductivity type provided on the semiconductor substrate 102, where the first semiconductor layer 103 is lower in impurity concentration than the semiconductor substrate 102; first impurity regions 104 of the second conductivity type provided in upper portions of the first semiconductor layer 103 in the pixel area; second impurity regions 105 of the first conductivity type provided between the plurality of the first impurity regions 104 adjacent to each other in the pixel area and in the peripheral circuit area; and third impurity regions 106 of the first conductivity type expanded from a position directly under the second impurity regions 105 toward the semiconductor substrate 102 in the pixel area.

### TECHNICAL FIELD

The technique described in the specification relates to solid state imaging devices including a pixel area in which a plurality of light receiving elements (e.g., p-n photodiodes) is arranged on a semiconductor substrate, and a peripheral circuit part by which signals from the light receiving elements are output to the outside, and specifically to MOS-type image sensors.

### BACKGROUND ART

In recent years, emphasis has been placed on miniaturization of metal-oxide-semiconductor (MOS)-type image sensors and charge coupled device (CCD)-type image sensors. For miniaturization, the area of photodiodes for photoelectric conversion is reduced along with the size of pixels. A reduction in sensitivity due to scaling down of the photodiodes is a serious problem for the image sensors. Moreover, for image sensors applied to car-mounted cameras for nighttime drive support and to security cameras for night vision, there is a need to increase the sensitivity to near-infrared light (wavelength: 650 nm or longer) which is invisible to human eyes, and is suitable as nighttime irradiating light.

FIG. 1 illustrates, for light of different wavelengths, the relationship between the depth in a silicon substrate and the light intensity ratio at respective levels in the depth. Here, the light intensity ratio is a value obtained from the expression: (light intensity I at the respective levels in the depth in the silicon substrate)/(light intensity I₀ at an upper surface of the silicon substrate). The light intensity ratio of short-wavelength light approaches 0 in a shallow region in the silicon substrate. This is because short-wavelength light has a high absorption coefficient, and thus is mostly absorbed in the shallow region in the substrate. By contrast, long-wavelength light has a low absorption coefficient, and thus is not absorbed but arrives at a deep region in the silicon substrate. When photodiodes are expanded to a deeper position in the substrate, electric charges generated by photoelectric conversion of long-wavelength light can be collected to the photodiodes, thereby allowing the sensitivity to be increased. To expand the photodiodes to the deeper position in the substrate, the following two methods may be possible.

In a first method, n-type impurity regions of photodiodes are expanded in a depth direction of a substrate, and in a second method, depletion layers of photodiodes are expanded to a deeper position in a substrate.

In the first method, the potential of the photodiodes is high, and thus not all of electric charges stored in the photodiodes can be transferred, so that image lag is likely to occur. Therefore, the second method is generally used to improve the sensitivity.

Conventional techniques for the present invention will be described below with reference to the drawings.

—Conventional Technique 1—

FIG. 8 illustrates a configuration of a photodiode described in PATENT DOCUMENT 1. This configuration includes a p-type well layer 12 formed over a semiconductor substrate 11, an n-type light receiving region 17 formed in the p-type well layer 12, a p-type deep well layer 16 formed under the light receiving region 17, and a p-type impurity layer 20 formed between the light receiving region 17 and the deep-well layer 16. The p-type impurity layer 20 is lower in impurity concentration than the deep-well layer 16. The deep-well layer 16 is lower in impurity concentration than the well layer 12. This configuration has been taken as being possible for a depletion layer of the photodiode to be expanded to improve the sensitivity. However, in this configuration, the depletion layer of the photodiode is expanded to the region of the impurity layer 20, but is not expanded to the region of the deep-well layer 16 which is higher in impurity concentration than an impurity layer provided in a lower portion of the impurity layer 20. Therefore, it is not possible to sufficiently obtain the effect produced by expanding the depletion layer (e.g., the effect of improving the sensitivity).

—Conventional Technique 2—

By contrast, when depletion layers of photodiodes are sufficiently expanded in a depth direction of a substrate, the photodiodes adjacent to each other may be electrically connected, which may lead to crosstalk caused by leakage of electric charges. As a technique for reducing the crosstalk, a structure described in PATENT DOCUMENT 2 is illustrated in FIG. 9. A solid state imaging device is illustrated which includes: an imaging area in which a plurality of unit cells each including a photoelectric conversion part 22 and a signal scanning circuit is two-dimensionally arranged in rows and columns in a semiconductor substrate or a well 21; and signal lines for reading signals from the cells. The solid state imaging device includes three-level-configuration device isolation regions each of which is composed of: a device isolation region 24 isolating the photoelectric conversion parts 22 from each other; a p-type impurity layer 24-1 formed under the device isolation region 24, where the p-type impurity layer 24-1 has the same conductivity type as that of the substrate or the well in which the cells are arranged; and a second impurity isolation layer 24-2 formed under the p-type impurity layer. Since this configuration includes the isolation region expanded to a deeper position in the substrate, this configuration has been taken as being capable of reducing the crosstalk. However, in the structure described in PATENT DOCUMENT 2 in which the impurity layers are formed only under the device isolation regions isolating the photoelectric conversion parts from each other, when the device isolation regions are narrowed for miniaturization, the deep isolation regions (24-1, 24-2) are also narrowed along with the device isolation regions 24, so that the photodiodes cannot be sufficiently isolated from each other in the deeper position in the substrate.

### CITATION LIST

### Patent Document

PATENT DOCUMENT 1: Japanese Patent No. 3886297

PATENT DOCUMENT 2: Japanese Patent No. 3403062

### SUMMARY OF THE INVENTION

### Technical Problem

The present invention was devised in view of the problems discussed above. It is an object of the present invention to provide a solid state imaging device in which a depletion layer can be sufficiently expanded to a deeper position in a substrate (the sensitivity can be improved), and even if device isolation regions are narrowed, the leakage of electric charges between adjacent photodiodes can be sufficiently reduced.

### Solution to the Problem

A solid state imaging device according to an example of the present invention is a solid state imaging device having a pixel area in which a plurality of light receiving elements are arranged, and a peripheral circuit area adjacent to the pixel area, the solid state imaging device including: a semiconductor substrate of a first conductivity type or a second conductivity type; a first semiconductor layer of the first conductivity type provided on the semiconductor substrate, where the first semiconductor layer is lower in impurity concentration than the semiconductor substrate; first impurity regions of the second conductivity type provided in upper portions of the first semiconductor layer in the pixel area; second impurity regions of the first conductivity type provided between the plurality of first impurity regions adjacent to each other in the pixel area and in the peripheral circuit area; and third impurity regions of the first conductivity type expanded from a position directly under the second impurity regions toward the semiconductor substrate in the pixel area.

With this configuration, depletion layers of photodiodes are not hindered by the impurity layers, and can be sufficiently expanded to a deeper position in the substrate. Moreover, since the semiconductor substrate of a first conductivity type or a second conductivity type which is higher in impurity concentration than the first semiconductor layer is used, electric charges generated by photoelectric conversion under the region to which the depletion layers are expanded can disappear by recombination in the semiconductor substrate, or can be swept out into the substrate due to an overflow drain structure, so that it is possible to reduce the leakage of the electric charges between the photodiodes. Moreover, since the second impurity regions and the third impurity regions expanded from a position directly under the second impurity regions toward the semiconductor substrate are provided between the first impurity regions adjacent to each other in the pixel area, the leakage of the electric charges between the photodiodes can be sufficiently reduced in the deeper position in the substrate. Furthermore, even when device isolation regions are narrowed, the leakage of the electric charges between the photodiodes adjacent to each other can be sufficiently reduced even in the case of miniaturization because the third impurity regions serving as isolation in the deeper position in the substrate are formed directly under the second impurity regions.

In the solid state imaging device according to the example of the present invention, the third impurity regions in the pixel area may be inside the second impurity regions in the pixel area. With this configuration, the leakage of the electric charges between the photodiodes in the deeper position in the substrate can be reduced, and the second impurity regions constituting the photodiodes can be expanded in a lateral direction, so that it is possible to improve the sensitivity.

In the solid state imaging device of the present invention, the third impurity regions in the pixel area may be in contact with the semiconductor substrate. With this configuration, it is possible to completely prevent the leakage of the electric charges between the photodiodes in the deeper position in the substrate.

In the solid state imaging device of the present invention, it is preferable that the first semiconductor layer has an impurity concentration of greater than or equal to 1×10¹⁴ atoms/cm³ and less than or equal to 1×10¹⁵ atoms/cm³. With this configuration, it is possible to sufficiently expand the depletion layers to the deeper position in the substrate while reducing variations between the photodiodes.

In the solid state imaging device according to the example of the present invention, the first semiconductor layer may be an epitaxially grown layer. With this configuration, it is possible to easily control the thickness of the first semiconductor layer, so that the depletion layers can be sufficiently expanded to the deeper position in the substrate.

In the solid state imaging device according to the example of the present invention, the first semiconductor layer may have a uniform impurity concentration. With this configuration, the depths of the depletion layers of the photodiodes are uniform, and thus the variations can be reduced.

In the solid state imaging device according to the example of the present invention, floating diffusions or transistors configured to reset electric charges in the light receiving elements are provided in the second impurity regions in the pixel area. With this configuration, it is possible to further reduce the leakage of the electric charges from the photodiodes to floating diffusion sections, and to obtain better operation characteristics of the transistors.

### ADVANTAGES OF THE INVENTION

With the configuration of the solid state imaging device of the present invention, it is possible to sufficiently extend the depletion layers of the photodiodes to the deeper position in the substrate, which allows the sensitivity to near-infrared light to be increased. Moreover, even if the depletion layers are expanded to the deeper position in the substrate for miniaturization, it is possible to reduce the leakage of the electric charges between the photodiodes in the deeper position in the substrate.

### BRIEF DESCRIPTION OF THE DRAWINGS

FIG. 1 is a graph illustrating, for light of different wavelengths, the relationship between the depth in a silicon substrate and the light intensity ratio at respective levels in the depth.

FIG. 2 is a plan view schematically illustrating an overall configuration of a solid state imaging device according to Embodiment 1 of the present invention.

FIG. 3 is a cross-sectional view illustrating an example configuration of the solid state imaging device according to Embodiment 1 along the line of FIG. 2.

FIG. 4 is a cross-sectional view illustrating a solid state imaging device according to Embodiment 2 along a line corresponding to the line of FIG. 2.

FIG. 5 is a cross-sectional view of a solid state imaging device according to Embodiment 3 along a line corresponding to the line of FIG. 2.

FIG. 6 is a graph illustrating the dependence of the sensitivity to light having a wavelength of 800 nm on the thickness of a p-type semiconductor layer.

FIG. 7 is a cross-sectional view illustrating a solid state imaging device according to Embodiment 7 along a line corresponding to the line of FIG. 2.

FIG. 8 is a diagrammatic cross-sectional view illustrating a solid state imaging device of a first conventional technique for expanding a depletion layer.

FIG. 9 is a diagrammatic cross-sectional view illustrating a solid state imaging device of a second conventional technique for reducing crosstalk.

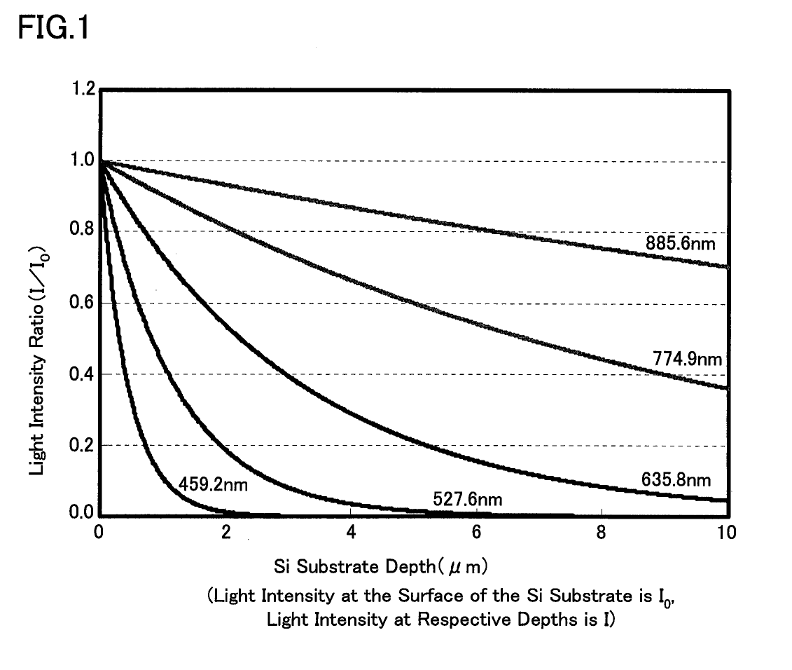

### DESCRIPTION OF EMBODIMENTS

Embodiments of the present invention will be described below with reference to the drawings.

### Embodiment 1

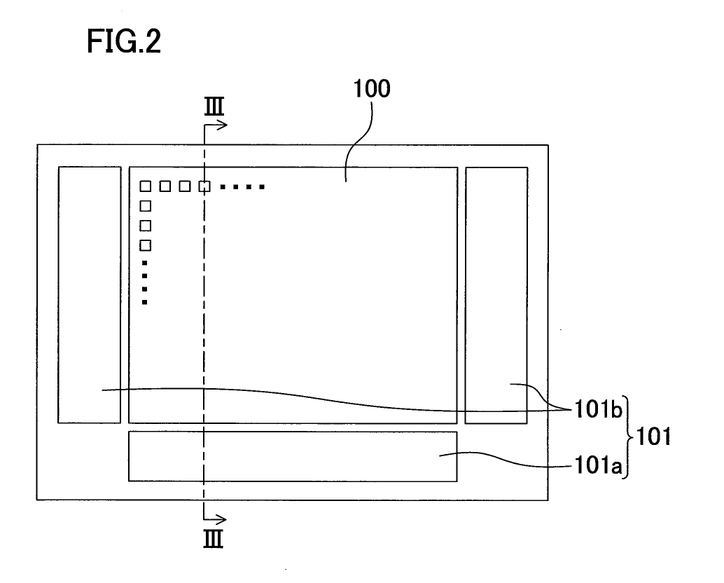

FIG. 2 is a plan view schematically illustrating an overall configuration of a solid state imaging device according to Embodiment 1 of the present invention. The figure is a view observed from an upper surface side of a substrate (where the upper surface is a surface on which a semiconductor devices are formed). As illustrated in FIG. 2, the solid state imaging device of the present embodiment includes: a pixel area 100 in which a plurality of light receiving elements (and pixels including the light receiving elements) for photoelectric conversion is arranged in a matrix pattern; and a peripheral circuit area 101 adjacent to the pixel area 100. Here, the peripheral circuit area 101 is provided along sides of the pixel area 100. The peripheral circuit area 101 includes circuits relevant to reading signals, for example, vertical shift registers 101b configured to select pixels from which signals are to be read, and a horizontal shift register 101a configured to output the signals read from the pixels to the outside of the solid state imaging device.

The signals output from the pixels are read and output to the outside of the solid state imaging device by using the vertical shift registers 101b and the horizontal shift register 101a. Note that in FIG. 2, a detailed illustration of the structure of MOS transistors provided in the areas and wiring is omitted.

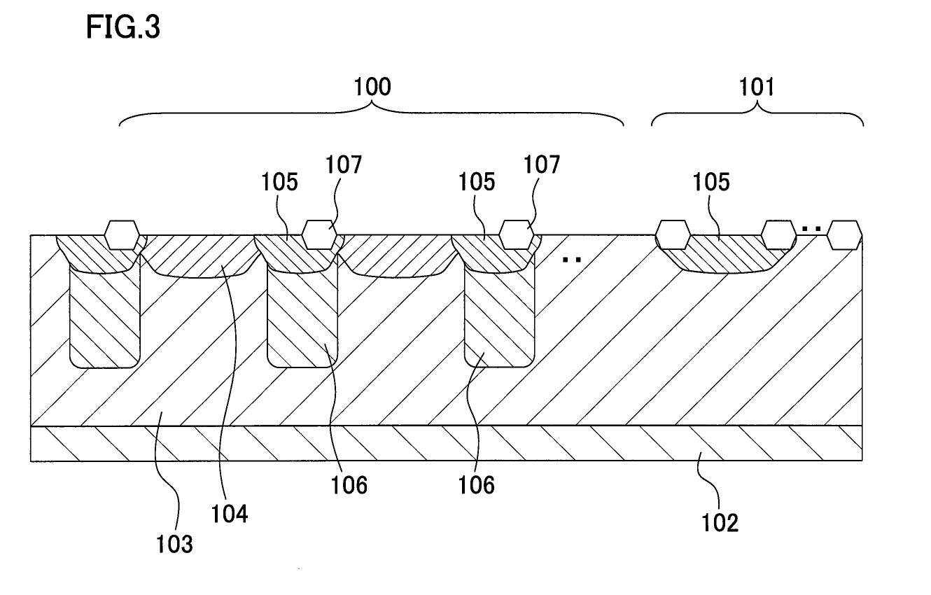

FIG. 3 is a cross-sectional view illustrating an example configuration of the solid state imaging device according to Embodiment 1 along the line III-III of FIG. 2.

As illustrated in the figure, the solid state imaging device of the present embodiment includes the pixel area 100 and the peripheral circuit area 101, and the pixels in the pixel area 100 are isolated from each other by an isolation oxide film 107. The isolation oxide film 107 is formed by LOCOS or STI. In the figure, an example structure formed by LOCOS is illustrated. The solid state imaging device includes: a semiconductor substrate 102; a p-type semiconductor layer (first semiconductor layer) 103 provided on the semiconductor substrate 102, where the p-type semiconductor layer is lower in impurity concentration than the semiconductor substrate 102; n-type impurity regions (first impurity regions) 104 provided in upper portions of the p-type semiconductor layer 103 in the pixel area 100; p-type well regions (second impurity regions) 105 provided between the n-type impurity regions 104 and in the peripheral circuit area 101; and p-type deep isolation regions (third impurity regions) 106 expanded from a position directly under the p-type well regions 105 toward the semiconductor substrate 102 in the pixel area 100. Note that the p-type deep isolation regions 106 may be formed not only in the pixel area 100 but formed also directly under the p-type well region 105 in the peripheral circuit area 101 without impairing the effect of the present invention.

When viewed from the surface (upper surface) side of the semiconductor substrate 102, the p-type well regions 105 in the pixel area 100 surround the n-type impurity regions 104. Moreover, the p-type deep isolation regions 106 expanded from a position directly under the p-type well regions 105 toward the semiconductor substrate 102 also surround the n-type impurity regions 104. Examples of the impurity concentration in the impurity regions will be given. The p-type semiconductor layer 103 has an impurity concentration of about 1×10¹⁵ atoms/cm³. The n-type impurity regions 104 have an impurity concentration of about 1×10¹⁶ atoms/cm³. The p-type well regions 105 have an impurity concentration of about 1×10¹⁶ atoms/cm³. The p-type deep isolation regions have an impurity concentration of about 1×10¹⁶ atoms/cm³. Next, examples of depths of the impurity regions from the surface of the semiconductor substrate will be given. The p-type semiconductor layer 103 has a thickness of about 4-5 μm. The p-type well regions 105 and the n-type impurity regions 104 are formed to have a depth of about 1 μm from the surface of the substrate. The p-type deep isolation regions 106 are formed to have a depth of about 3-4 μm from the surface of the substrate.

As described above, in the solid state imaging device of the present embodiment, in the p-type semiconductor layer 103 having a low impurity concentration provided on a p-type or n-type substrate having a high impurity concentration, the n-type impurity regions 104 are formed, thereby constituting photodiodes. Moreover, in the pixel area 100, the p-type well regions 105 are formed between the n-type impurity regions 104, and the p-type isolation regions are expanded from a position directly under the p-type well regions 105 toward the semiconductor substrate. In this configuration, since no impurity region hindering the expansion of depletion layers is provided in a depth direction of the semiconductor substrate, the depletion layers can be sufficiently expanded to the deeper position in the substrate, so that it possible to increase the sensitivity to long-wavelength light which is not absorbed but arrives at the deeper position in the substrate. Moreover, since a p-type or n-type substrate having a high impurity concentration is used, electric charges generated by photoelectric conversion under the region in which the depletion layers are formed can disappear by recombination, or the electric charges can be swept out into the substrate due to an overflow drain structure, so that it is possible to reduce the leakage of the electric charges between the photodiodes. Furthermore, since the p-type deep isolation regions having a high concentration are expanded from a position directly under the p-type well regions toward the semiconductor substrate, the leakage of electric charges between the photodiodes in the deeper position in the substrate can be reduced even if the isolation oxide film 107 is narrowed for miniaturization.

Here, when the semiconductor substrate 102 has a high impurity concentration, and is p-type, the impurity concentration is preferably greater than or equal to 1×10¹⁸ atoms/cm³ and less than or equal to 1×10²° atoms/cm³. With this configuration, the semiconductor substrate 102 has a gettering effect, and can also reduce noise. Moreover, the p-type semiconductor substrate 102 also offers an advantage of lower cost than an n-type substrate. Alternatively, when the semiconductor substrate 102 is n-type, electric charges generated by photoelectric conversion under the region in which the depletion layers are formed are swept out due to an overflow drain structure, so that it is possible to further reduce the leakage of electric charges at the time of oversaturation compared to the p-type substrate in which the electric charges disappear by recombination.

### Embodiment 2

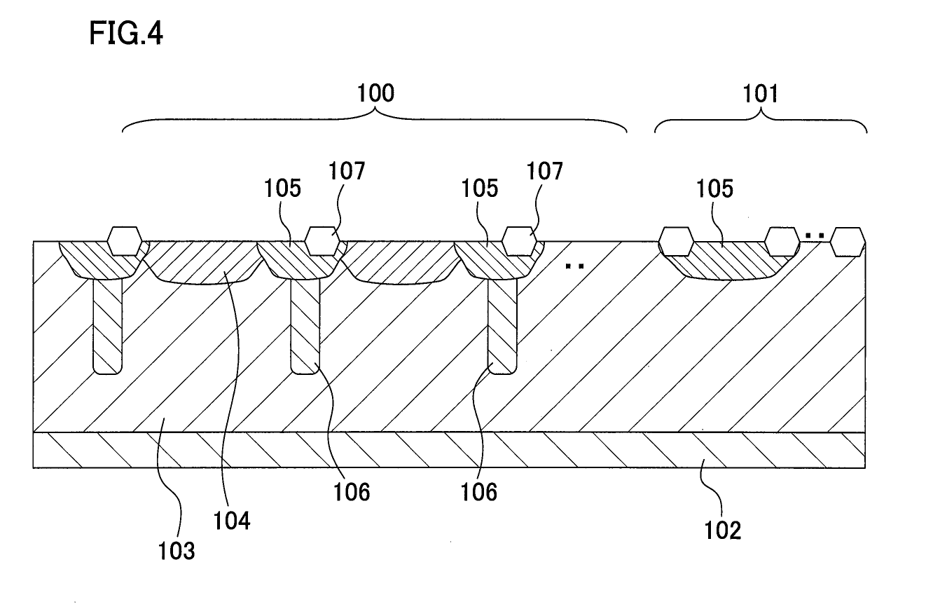

An overall configuration of a solid state imaging device according to Embodiment 2 of the present invention is similar to that of the solid state imaging device of Embodiment 1, and thus the description of the similar configuration will be simplified or omitted. The following description will be given with reference to FIG. 4.

In the solid state imaging device of the present embodiment, p-type deep isolation regions 106 are formed inside p-type well regions 105 in a pixel area 100 when viewed from above. With this configuration, it is possible not only to reduce the leakage of electric charges between photodiodes adjacent to each other in a deeper position in a substrate in the pixel area 100, but it is possible also to expand n-type impurity regions 104 constituting the photodiodes in a lateral direction (a direction horizontal to a surface of the substrate). Since the area of the photodiodes in the deeper position in the substrate is increased, the sensitivity can be improved.

### Embodiment 3

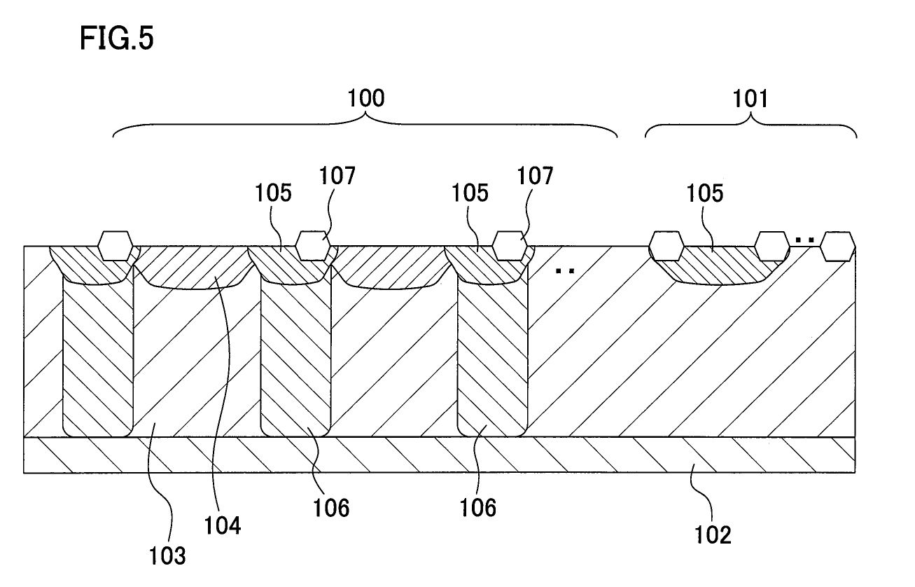

An overall configuration of a solid state imaging device according to Embodiment 3 of the present invention is similar to that of the solid state imaging device of Embodiment 1, and thus the description of the similar configuration will be simplified or omitted. The following description will be given with reference to FIG. 5.

In the solid state imaging device of the present embodiment, p-type deep isolation regions 106 in a pixel area 100 are in contact with a semiconductor substrate 102. With this configuration, it is possible to almost completely prevent the leakage of electric charges between photodiodes adjacent to each other in a deeper position in the substrate in the pixel area.

### Embodiment 4

An overall configuration of a solid state imaging device according to Embodiment 4 of the present invention is similar to that of the solid state imaging device of Embodiment 1, and thus the description of the similar configuration will be simplified or omitted.

In the solid state imaging device of the present embodiment, a p-type semiconductor layer 103 has an impurity concentration of greater than or equal to 1×10¹⁴ atoms/cm³ and less than or equal to 1×10¹⁵ atoms/cm³. A depletion layer width W [cm] will be shown in the following relational expression (Equation 1). Here, εs is the dielectric constant [F/cm] of a semiconductor, q is an elementary electric charge [C], Vbi is a built in potential [V], and ND is a donor impurity concentration [cm⁻³].

$$W = \sqrt{\frac{2 {ɛ}_{s} {V}_{bi}}{{qN}_{D}}} \qquad ( Equation 1 )$$

When the donor impurity concentration is low, the depletion layer width is large. Thus, when the impurity concentration of the p-type semiconductor layer 103 is low, depletion layers of photodiodes are expanded to a deeper position in a substrate. However, when the impurity concentration of the p-type semiconductor layer 103 is lowered, it becomes difficult to control its uniformity. When the impurity concentration is greater than or equal to 1×10¹⁴ atoms/cm³ and less than or equal to 1×10¹⁵ atoms/cm³, the depletion layers of the photodiodes can be sufficiently expanded to the deeper position in the substrate, and the concentration can be controlled to be uniform, so that it is possible to reduce variations of signal outputs between the photodiodes caused by the difference in depth of the depletion layers.

### Embodiment 5

An overall configuration of a solid state imaging device according to Embodiment 5 of the present invention is similar to that of the solid state imaging device of Embodiment 1, and thus the description of the similar configuration will be simplified or omitted.

In the solid state imaging device of the present embodiment, a p-type semiconductor layer 103 is formed by epitaxial growth. In the case of forming a p-type semiconductor layer by multi-stage ion implantation, the depth of the semiconductor layer is limited due to the restriction of the specifications of apparatuses.

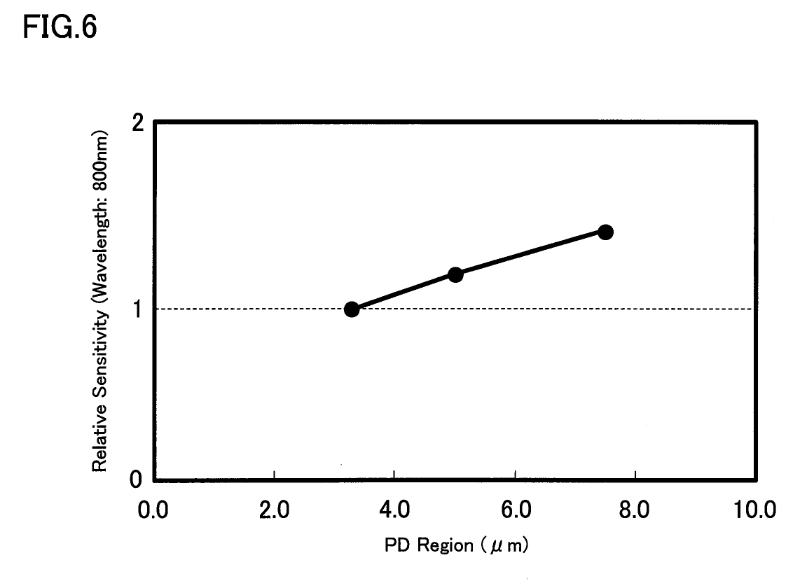

By contrast, in the case of forming the p-type semiconductor layer 103 by epitaxial growth, it is possible to freely control the thickness of the layer. FIG. 6 illustrates the sensitivity to light having a wavelength of 800 nm (relative sensitivity, where the sensitivity with respect to a thickness of 3.3 μm is 1) when the thickness of the p-type semiconductor layer 103 is increased to 3.3 μm, 5.0 μm, and 7.5 μm by epitaxial growth. As the thickness of the p-type semiconductor layer 103 increases, the sensitivity improves. As to depletion layers of photodiodes composed of the p-type semiconductor layer 103 and n-type impurity regions 104, the larger the thickness of the p-type semiconductor layer 103 is, the deeper position in the substrate the p-type semiconductor layer 103 can be expanded to, so that it is possible to improve the sensitivity to long-wavelength light.

### Embodiment 6

An overall configuration of a solid state imaging device according to Embodiment 6 of the present invention is similar to that of the solid state imaging device of Embodiment 1, and thus the description of the similar configuration will be simplified or omitted.

In the solid state imaging device of the present embodiment, a p-type semiconductor layer 103 has a uniform impurity concentration. Since the sensitivity of photodiodes is determined by the depth of depletion layers expanded in a deeper position in a substrate, variations of the impurity concentration in a pixel area 100 may cause the difference in sensitivity between the plurality of photodiodes in the pixel area 100, thereby varying signal outputs. For example, unlike the case of forming the p-type semiconductor layer 103 by ion implantation, the p-type semiconductor layer 103 formed by epitaxial growth can have a uniform impurity concentration in the pixel area 100, so that it is possible to reduce variations of the signal outputs.

### Embodiment 7

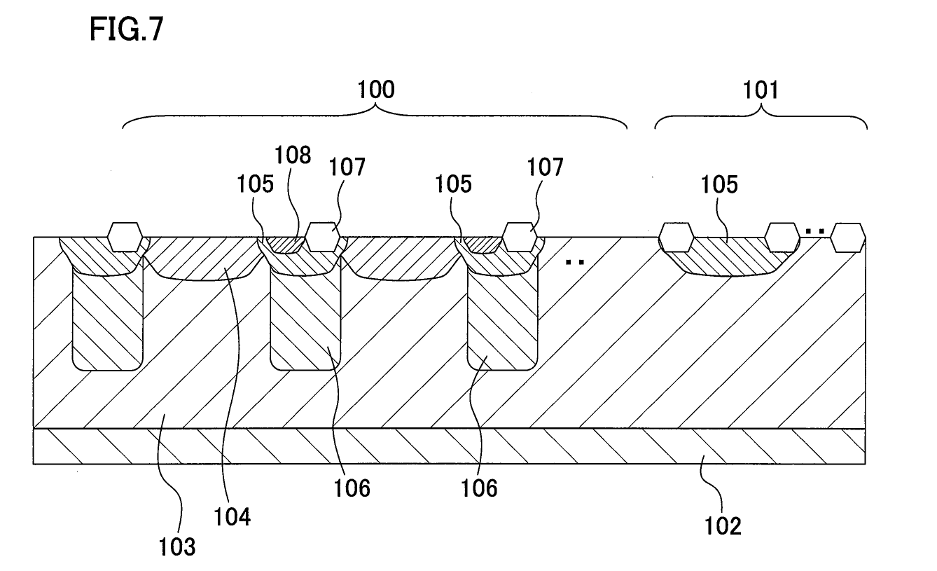

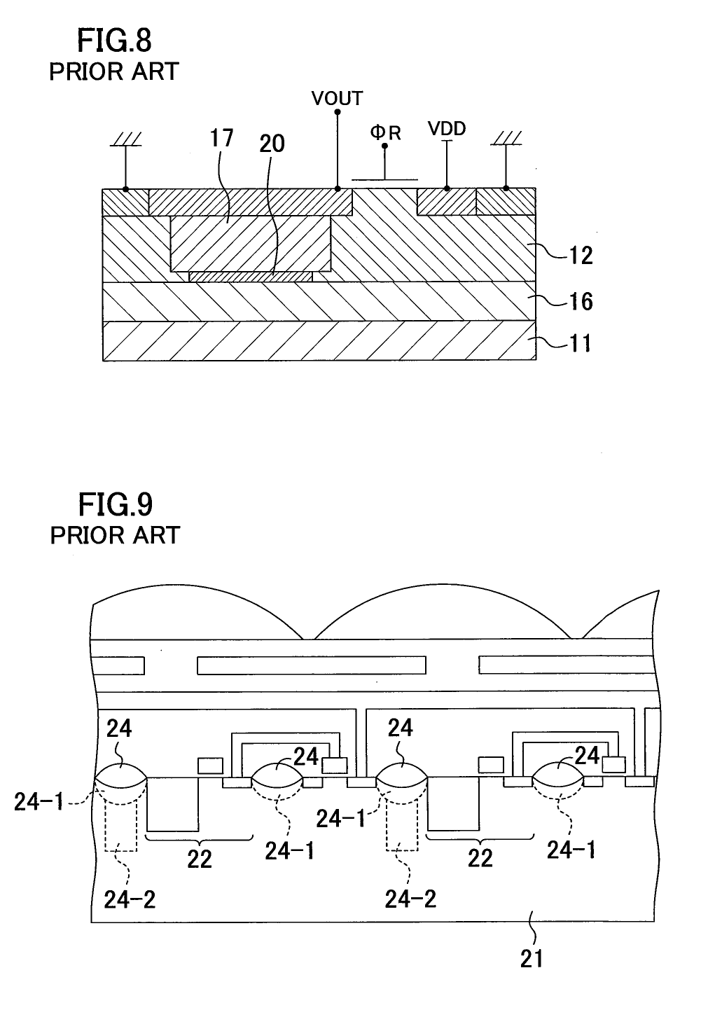

An overall configuration of a solid state imaging device according to Embodiment 7 of the present invention is similar to that of the solid state imaging device of Embodiment 1, and thus the description of the similar configuration will be simplified or omitted. The following description will be given with reference to FIG. 7.

In the solid state imaging device of the present embodiment, floating diffusions 108 or transistors (not shown) configured to reset electric charges of light receiving elements are provided in p-type well regions 105 in a pixel area 100. In the solid state imaging device illustrated in FIG. 7, as an example, the floating diffusions 108 are provided. When the floating diffusions 108 or the transistors are formed in the p-type well regions 105 having p-type deep isolation regions expanded from a position directly under the p-type well regions 105 toward a semiconductor substrate 102, the floating diffusions 108 reduce unnecessary electric charges from photodiodes, and the transistors reduce unnecessary electric charges from the photodiodes to drains, so that it is possible to obtain satisfactory characteristics.

### INDUSTRIAL APPLICABILITY

As described above, in the solid state imaging device of the present invention, the sensitivity can be increased with crosstalk being reduced even in the case of miniaturization. Therefore, the solid state imaging device of the present invention is useful for various kinds of imaging apparatuses such as car-mounted cameras for night time drive support and security cameras for night vision.

### DESCRIPTION OF REFERENCE CHARACTERS

100 Pixel Area
101 Peripheral Circuit Area
101a Horizontal Shift Register
101b Vertical Shift Register
102 Semiconductor Substrate
103 P-type Semiconductor Layer
104 N-type Impurity Region
105 P-type Well Region
106 P-type Deep Isolation Region
107 Isolation Oxide Film
108 Floating Diffusion

1-7. (canceled)

8. A solid state imaging device having a pixel area in which a plurality of light receiving elements are arranged, and a peripheral circuit area adjacent to the pixel area, the solid state imaging device comprising:
a semiconductor substrate of a first conductivity type or a second conductivity type;
a first semiconductor layer of the first conductivity type provided on the semiconductor substrate, where the first semiconductor layer is lower in impurity concentration than the semiconductor substrate;
first impurity regions of the second conductivity type provided in upper portions of the first semiconductor layer in the pixel area;
second impurity regions of the first conductivity type provided in a region surrounding the first impurity regions and in the peripheral circuit area; and
third impurity regions of the first conductivity type expanded from a position directly under the second impurity regions toward the semiconductor substrate in the pixel area.

9. The solid state imaging device of claim 8, wherein
the third impurity regions in the pixel area are in the second impurity regions in the pixel area when viewed from above.

10. The solid state imaging device of claim 8, wherein
the third impurity regions in the pixel area are in contact with the semiconductor substrate.

11. The solid state imaging device of claim 8, wherein
the first semiconductor layer has an impurity concentration of greater than or equal to 1×10¹⁴ atoms/cm³ and less than or equal to 1×10¹⁵ atoms/cm³.

12. The solid state imaging device of claim 8, wherein
floating diffusions or transistors configured to reset electric charges of the light receiving elements are provided in the second impurity regions in the pixel area.
